(19) United States
(12) Patent Application Publication
(10) Pub. No.: US 2015/0294756 A1
(43) Pub. Date: Oct. 15, 2015

(54) FLEXIBLE CONDUCTING MATERIALS AND METHODS FOR THE MANUFACTURE THEREOF

(71) Applicant: Enhanced Surface Dynamics, Inc., Palo Alto, CA (US)

(72) Inventors: Amir Ben Shalom, Modiin (IL); Lior Greenstein, Tel Aviv (IL); Erez Steiner, Kfar Netter (IL); Doron Teomim, Modiin (IL)

(21) Appl. No.: 14/437,556

(22) PCT Filed: Oct. 21, 2013
(86) PCT No.: PCT/IB13/59499

§ 371 Date: Apr. 22, 2015

Related U.S. Application Data
(60) Provisional application No. 61/716,784, filed on Oct. 22, 2012.

(51) Int. Cl. H01B 5/14; G08B 21/04; D06M 11/83; D06B 1/00; C25D 7/00; C23C 14/34

(52) U.S. Cl. CPC H01B 5/14; C25D 7/00; C23C 14/34; D06M 11/83; D06B 1/00; G08B 21/0461; D06M 2101/34

(57) ABSTRACT

A flexible conductive material may be a selectively conductive textile fabricated by intertwining yarns having different affinities to conductive impregnation. Another flexible conductive material may be formed from an array of conductive elements connected via sinuous connecting wires embedded in a flexible host material. The regions having a high conductivity may serve as conductive electrodes, for example of a pressure sensing mat.

### FIELD AND BACKGROUND OF THE DISCLOSURE

The disclosure herein relates to flexible conductors. In particular the disclosure relates to flexible materials and fabrics incorporating conducting elements and methods of manufacture thereof.

Flexible conductors may be used in a variety of applications where rigidity of the conductor is not required or may be problematic. For example conductive textiles may be used to manufacture smart clothing and the like.

Nevertheless, flexible conductors have been costly to produce involving specialized equipment such as looms capable of weaving metallic threads and the like. Furthermore manufacturers of flexible conductors often have to compromise required mechanical properties of the materials in order to provide the required electrical properties.

There is therefore a need for practical flexible conductors and a cost effective method of their manufacture. The present disclosure addresses this need.

### SUMMARY

It is one aspect of the current disclosure to teach a method for manufacturing a conductive textile. The method may comprise obtaining at least a first yarn comprising a first material having a first affinity to conductive impregnation; obtaining at least a second yarn comprising a second material having a second affinity to conductive impregnation; intertwining the first yarn and the second yarn into a cloth having at least a first region having the first affinity to conductive impregnation and at least a second region having the second affinity to conductive impregnation; and impregnating the cloth with conductive material thereby producing a conductive cloth having a first region having a first conductivity and a second region having a second conductivity.

Optionally, the step of impregnating the cloth with conductive material may utilize a process selected from at least one of the group consisting of: electroless plating, electroplating, painting, dying, sputtering, evaporative depositing, coating with metal, coating with a conducting polymer and combinations thereof.

Optionally, the step of intertwining the first yarn and the second yarn comprises a process selected from at least one of the group consisting of: knitting, weaving, crocheting, tufting, embroidering and combinations thereof.

Variously, the first material may be selected from at least one of the group consisting of: nylon, cotton, wool, polyester, linen, hair, pashmina, silk, sinew, hemp, cellulose, rayon, acrylic, spandex, polythene and combinations thereof. Similarly, the second material may be selected from at least one of the group consisting of: nylon, cotton, wool, polyester, linen, hair, pashmina, silk, sinew, hemp, cellulose, rayon, acrylic, spandex, polythene and combinations thereof.

According to another aspect of the disclosure, a conductive textile is presented comprising at least a first yarn and at least a second yarn intertwined to form a cloth wherein the first yarn comprises a first material having a first affinity to conductive impregnation and the second yarn comprises a second material having a second affinity to conductive impregnation and the cloth is impregnated with conductive material such that the cloth has a first region having a first conductivity and a second region having a second conductivity.

A further aspect of the disclosure is to present a pressure detection mat comprising: at least one layer of an insulating material sandwiched between a first layer of the conductive textile and second layer of the conductive textile, wherein the strip electrodes of the first layer and the strip electrodes of the second layer overlap at a plurality of intersections. The pressure detection mat may further comprise a driving unit configured to supply electrical potential selectively to the conducting strips of the first layer; a control unit wired to the conductive strips of the second layer and operable to control the driving unit; a processor configured to monitor electrical potential on the conductive strips of the second layer, to calculate impedance values for each intersection and to determine pressure applied to the intersection; and at least one display configured to present indications of pressure distribution to at least one caretaker. Accordingly, the caretaker may take pressure relieving action upon the subject.

In still another aspect of the disclosure, a flexible pressure detection platform is presented comprising at least one layer of insulating material sandwiched between a first electrode layer and a second electrode layer, each the electrode layer comprising an array of strip electrodes embedded in a flexible material. Each strip electrode may comprise: a plurality of segments of conductive material; a connecting wire in conductive contact with the segments, the connecting wire having a length exceeding the length of the strip electrode such that the connecting wire adopts a sinuous configuration along the strip electrode; and a flexible laminate into which the segments and the connecting wire are embedded. The first electrode layer and the second electrode layer may be orientated such that the strip electrodes of the first electrode layer and the strip electrodes of the second electrode layer overlap at a plurality of intersections.

According to another aspect a flexible electrical conductor is introduced comprising a conducting wire embedded in a flexible material, wherein the conducting wire has a length exceeding that of the flexible material such that the conducting wire adopts a sinuous configuration along the conducting strip.

A further aspect of the disclosure is to present a pressure detection mat comprising: at least one layer of an insulating material sandwiched between a first electrode layer and a second electrode layer, the strip electrodes of the first electrode layer and the strip electrodes of the second electrode layer overlapping at a plurality of intersections; a first bundle of connecting wires for connecting the strip electrodes of the first electrode layer to a controller unit; a second bundle of connecting wires for connecting the strip electrodes of the second electrode layer to the controller unit; wherein each connecting wire is mechanically and conductively coupled to a single strip electrode via a conducting rivet.

Additionally a method is taught for manufacturing a conductive flexible material comprising: obtaining at least one sheet of flexible material having a first length; obtaining at least one conducting wire having a second length exceeding the first length; and embedding the conducting wire into the flexible material such that the conducting wire adopts a sinuous configuration along the conductive flexible material. Optionally, the step of embedding may comprise laminating the conducting wire with a flexible laminate.

Additionally or alternatively, the method further comprises: embedding a plurality of conducting segments into the flexible material; and connecting the plurality of conducting segments with the conducting wire.

It is noted that in order to implement the methods or systems of the disclosure, various tasks may be performed or completed manually, automatically, or combinations thereof. Moreover, according to selected instrumentation and equipment of particular embodiments of the methods or systems of the disclosure, some tasks may be implemented by hardware, software, firmware or combinations thereof using an operating system. For example, hardware may be implemented as a chip or a circuit such as an ASIC, integrated circuit or the like. As software, selected tasks according to embodiments of the disclosure may be implemented as a plurality of software instructions being executed by a computing device using any suitable operating system.

In various embodiments of the disclosure, one or more tasks as described herein may be performed by a data processor, such as a computing platform or distributed computing system for executing a plurality of instructions. Optionally, the data processor includes or accesses a volatile memory for storing instructions, data or the like. Additionally or alternatively, the data processor may access a non-volatile storage, for example, a magnetic hard-disk, flash-drive, removable media or the like, for storing instructions and/or data. Optionally, a network connection may additionally or alternatively be provided. User interface devices may be provided such as visual displays, audio output devices, tactile outputs and the like. Furthermore, as required, user input devices may be provided such as keyboards, cameras, microphones, accelerometers, motion detectors or pointing devices such as mice, roller balls, touch pads, touch sensitive screens or the like.

### BRIEF DESCRIPTION OF THE FIGURES

For a better understanding of the embodiments and to show how they may be carried into effect, reference will now be made, purely by way of example, to the accompanying drawings.

With specific reference now to the drawings in detail, it is stressed that the particulars shown are by way of example and for purposes of illustrative discussion of selected embodiments only, and are presented in the cause of providing what is believed to be the most useful and readily understood description of the principles and conceptual aspects. In this regard, no attempt is made to show structural details in more detail than is necessary for a fundamental understanding; the description taken with the drawings making apparent to those skilled in the art how the several selected embodiments may be put into practice. In the accompanying drawings:

FIG. 1 schematically represents an example of a selectively conducting fabric according to one embodiment of a conductive flexible material;

FIGS. 2A and 2B schematically represent a woven fabric comprising multiple yarn materials having different affinities to conductive impregnation;

FIGS. 2C and 2D schematically represent a possible method by which a multiple yarn woven material may be manufactured;

FIG. 3 is a flowchart representing selected actions of a method for manufacturing a selectively conducting fabric of the disclosure;

FIGS. 4A and 4B schematically represent isometric and exploded views of an example of a composite flexible conductive material including conducting wire embedded in a flexible laminate according to another embodiment of a conductive flexible material;

FIGS. 5A and 5B schematically represent top and isometric exploded views of another example of a composite flexible conductive material including conducting segments connected by a connecting wire and embedded into a flexible laminate according to another embodiment of the conductive flexible material;

FIG. 6 is a flowchart representing selected actions of a method for manufacturing a composite flexible conductive material of the disclosure;

FIG. 7A schematically represents a selectively conducting fabric wired to function as an array of strip electrodes;

FIG. 7B schematically represents a flexible conductive material in which an array of embedded conducting segments are wired to function as an array of strip electrodes;

FIGS. 8A-C schematically show a first example of a fastening for connecting a bundle of electrical connecting wires to a flexible conductive material;

FIGS. 8D and 8E schematically show a riveted fastening for connecting a bundle of electrical connecting wires to a flexible conductive material;

FIGS. 8F and 8G schematically show the riveted fastening used to connecting a bundle of electrical connecting wires to an array of embedded conducting segments wired to function as an array of strip electrodes;

FIG. 8H shows an exploded isometric view of a laminated array of conducting segments conductively riveted to a bundle of connecting wires;

FIGS. 9A-C schematically represent further examples of flexible conductive material having more complex conductive regions;

FIG. 10A schematically represents an exploded isometric view of a particular application of the disclosure in which selectively conducting fabric are configured to serve as electrode layers of a pressure sensing surface; and

FIG. 10B schematically represents an exploded isometric view of another embodiment of the pressure sensing surface in which composite flexible conductive materials are configured to serve as the electrode layers.

### DETAILED DESCRIPTION

Aspects of the present disclosure relate to conductive flexible materials and methods for their manufacture. Flexible conducting materials may be used in a variety of applications such as electronically enhanced clothing, flexible electrical devices, flexible electronic sensors and the like. Flexible conducting materials may be fabricated for example by producing composite materials combining materials having required mechanical properties with materials having the required electrical properties.

It is noted that flexible conductive materials may be used to incorporate electrical components into a variety of products. For example, smart clothing may be manufactured integrating electronic equipment such as media players, computing devices, lighting elements, heating elements and the like.

In some embodiments, a selectively conductive textile may be fabricated by weaving, knitting, crocheting, embroidering or otherwise intertwining a first yarn and a second yarn of different materials into a cloth. Where the first and second yarns have different affinities to conductive impregnation, a selectively conductive textile may be produced by treating the cloth such that the yarns having a higher affinity to conductive impregnation form regions having a high conductivity and other yarns having a lower affinity to conductive impregnation form regions having lower conductivity. Optionally, the regions having a high conductivity may serve as conductive electrodes or other conductors, for example, and the regions having low conductivity may serve as interspatial insulators.

In other embodiments, a composite flexible conductor may be fabricated by embedding conductive materials into a flexible laminate for example. Where required, such conductive materials may include electrical wires extending out of the laminate thereby facilitating their conductive coupling to connecting leads. For some applications particularly where conducting plates having large areas are required, for example to serve as capacitive plates, electrodes or the like, flexible conducting plates may be manufactured by embedding a plurality of conducting segments into a flexible laminate and electrically connecting these plates via one or more connecting wires in a required configuration.

It is noted that the systems and methods of the disclosure herein may not be limited in their application to the details of construction and the arrangement of the components or methods set forth in the description or illustrated in the drawings and examples. The systems and methods of the disclosure may be capable of other embodiments or of being practiced or carried out in various ways.

Alternative methods and materials similar or equivalent to those described herein may be used in the practice or testing of embodiments of the disclosure. Nevertheless, particular methods and materials are described herein for illustrative purposes only. The materials, methods, and examples are not intended to be necessarily limiting.

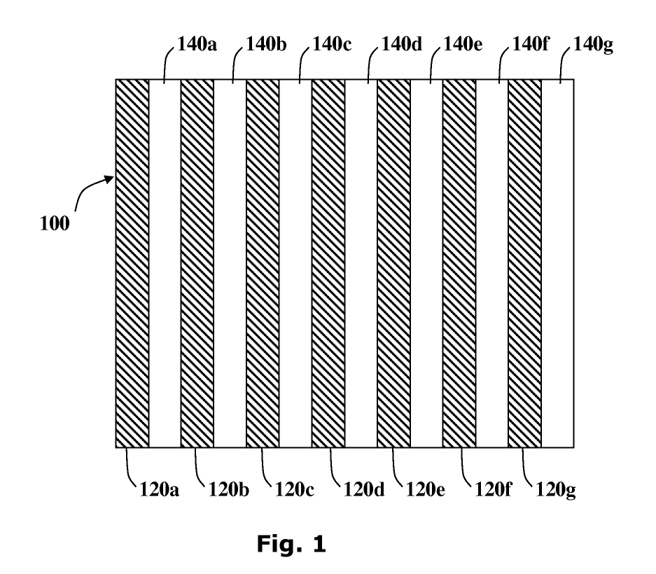

Reference is made to FIG. 1 which schematically represents an example of a conductive flexible material. Where required, requisite mechanical and electrical properties of a material may be provided by a selectively conducting fabric 100. The selectively conducting fabric 100 may include regions 120a-g (collectively 120), 140a-g (collectively 140) which have differing conductive characteristics. The first region 120 may have a high conductivity and a second region 140 may have a lower conductivity.

Manufacture of conductive textiles generally involves the weaving or knitting of conductive yarns into a fabric. Conductive fibers may be produced by a variety of methods such as draw blending metal slivers with slivers of textile fabrics before spinning, coating fibers with metallic salts or resins containing conductive particles, or the like. Conducting fibers or metal wire may be spun into yarns, for example by wrapping a conducting filament around a fibrous core, melt spinning bicomponent yarns with a carbon powder sheath, braiding a conductive material into the yarn, or the like.

Such conductive yarns, particularly those including metallic elements, may have different mechanical properties from most of the common yarns used in the textile industry. Accordingly, standard industrial looms and knitting machines may not be suitable for the production of conductive textiles. Consequently, the production of conducting textiles can be prohibitively costly for many applications.

In contradistinction to conductive textiles manufactured by weaving conducting yarns or sewing conducting cloth and non-conducting cloth together, the selectively conducting fabric 100 of the embodiment may be produced using untreated yarns as commonly used in the textile industry. For example, yarn materials may include nylon, cotton, wool, polyester, linen, hair, pashmina, silk, sinew, hemp, cellulose, rayon, acrylic, spandex, polythene and the like as well as combinations thereof. Such standard yarns may be used with standard industrial textile machines such as looms, knitting machines and the like.

Accordingly, the first region 120 may incorporate a first yarn of a first material and the second region 140 may incorporate a second yarn of a second material. It is a particular feature of the embodiment that the first material and the second material have different affinities to conductive impregnation. Therefore, after undergoing a conductive treatment, such as electroless plating, electroplating, painting with conductive paint, dying, sputtering, evaporative depositing, coating with metal, coating with a conducting polymer or the like, the resulting cloth displays different conductive characteristics in each region.

By way of example and for illustrative purposes only, a selectively conductive cloth may be fabricated by weaving or knitting untreated nylon yarns together with untreated polyester yarns to produce a cloth. It has surprisingly been found that when such a cloth is treated using electroless plating techniques such as submerging the cloth in a vat of metal salts, the conductive material impregnates the nylon to a much greater degree than it impregnates the polyester. Accordingly, the resulting cloth has regions of high conductivity, where the nylon yarns are present, and regions of low conductivity, where only polyester yarns are present. It will be appreciated that the affinity of conductive impregnation may depend upon various physical and chemical characteristics of the material of the yarn, such as its hydrophobicity, hydrophilicity, wettability, thermal conductivity or the like, as well as the methods of impregnation to which that material is subjected.

The term conductive impregnation as used herein refers to any method of treating a material with conductive particles such that its conductivity increases. The term does not exclusively refer to the filling of voids within the material and may also refer to coating, plating or indeed any other method of combining conducting particles with a material as described herein.

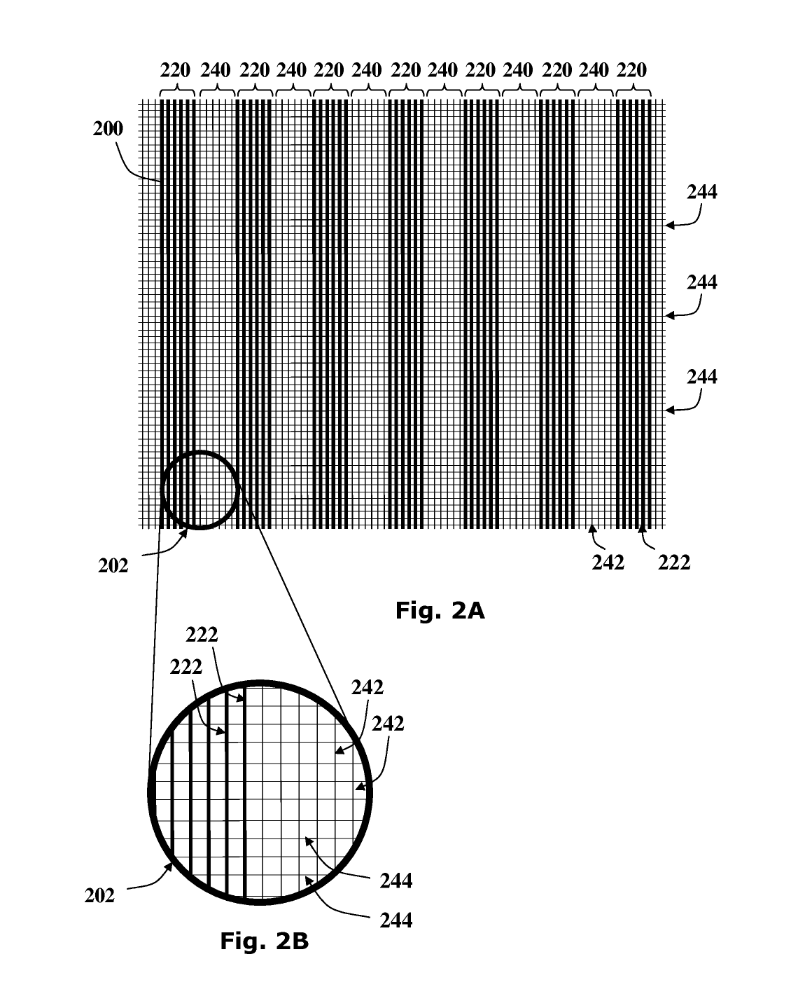

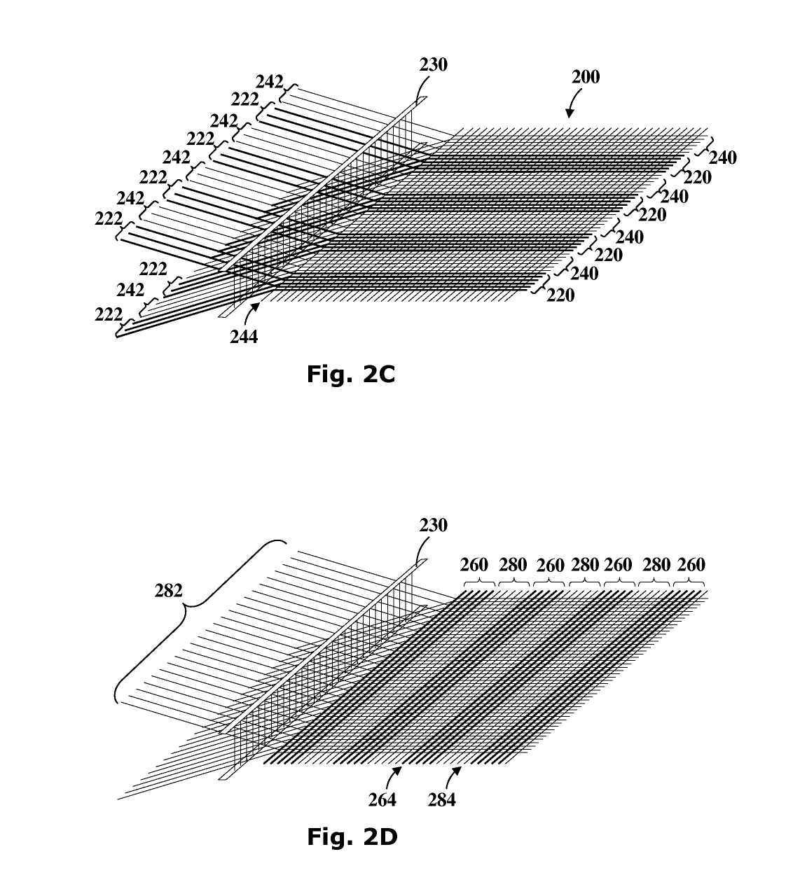

Reference is now made to FIGS. 2A and 2B showing a particular embodiment of the selectively conducting fabric, for the purposes of illustration. FIG. 2A schematically represents a section of selectively conductive woven fabric 200. The selectively conductive woven fabric 200 may include regions 220 of high conductivity and regions of low conductivity 240. For clarity, FIG. 2B shows an enlarged portion 202 of the selectively conductive woven fabric 200.

It is particularly noted that the woven fabric 200 comprises multiple intertwined yarns 222, 242, 244 of at least two types of yarn materials having different affinities to conductive impregnation. A first set of warp yarns 222 having a high affinity to conductive impregnation and a second set of warp yarns 242 having a lower affinity to conductive impregnation may be woven into a fabric together by a set of weft yarns 244. Optionally the weft yarns 244 may have still a third affinity to conductive impregnation. Alternatively, the weft yarns 244 may have the same affinity to conductive impregnation as the first set of warp yarns 222 or the second set of warp yarns 242.

The yarn materials may be selected to suit electrical, mechanical and other requirements. Many such materials are known in the art such as nylon, cotton, wool, polyester, linen, hair, pashmina, silk, sinew, hemp, cellulose, rayon, acrylic, spandex, polythene and the like. Such yarn materials will typically differ in their affinity to conductive impregnation by various methods, such as by electroless plating, electroplating, painting, dying, sputtering, evaporative depositing, coating with metal, coating with a conducting polymer and combinations thereof. Accordingly, yarns may be selected such that following treatment of the fabric 200, regions 220 of high conductivity are produced where the yarns 222 have a high affinity to conductive impregnation and regions of low conductivity 240 are produced where the yarns 242 have a low affinity to conductive impregnation.

Such a fabric 200 may be used to provide electrode strips for example, by selecting a weft yarn 244 of a material with a low affinity to conductive impregnation, such that after conductive impregnation treatment, the regions 220 of high conductivity remain electrically isolated from each other. For example, nylon warp yarns 222 may be used for the regions 220 of high conductivity with polyester warp yarns 242 may be used for the regions 240 of low conductivity and polyester weft yarns 244 used to weave the fabric.

FIGS. 2C and 2D schematically represent isometric views of looms upon which a selectively conductive fabric may be manufactured. In particular FIG. 2C represents how the cloth section of FIG. 2A may be manufactured by threading two types of warp yarns 222, 242 through a reed 230 and inserting a filling of weft yarn 244 through the shed region.

Alternatively, as shown in FIG. 2D, a common material may be used for all the warp yarns 282 threaded through the reed 230 while multiple weft yarns 264, 284 having characteristic affinities to conductive impregnation may be selectively inserted as required to form regions of high affinity to conductive impregnation 260 and regions of low affinity to conductive impregnation 280. For example, polyester warp yarns may be used together with two types of weft yarns, with polyester weft yarns 284 used to produce low conductivity regions and nylon weft yarns 264 used for high conductivity weft yarns.

Still other techniques involving multiple warp and weft types as known in the art may be used as applicable. Furthermore, although only weaving machines are represented in the example above, it will be appreciated that cloth manufacturing techniques may be used to produce the selectively conducting fabric, such as circular weaving, knitting, crocheting, embroidering, sewing, tufting and the like. Indeed, it is particularly noted that, because standard yarns are used, the selectively conducting fabric may be produced on standard looms, knitting machines, tufting machines, crocheting machines and the like as are common in the textile industry.

Alternatively, multiple weft yarns may be used to selectively connect sections of the fabric as required. For example, a strip of the fabric may be provided with a conductive channel stretching laterally across the electrodes. It is noted that such a conductive strip may be useful, for example for electroplating the electrodes, perhaps after an initial electroless plating phase. Such a strip may subsequently be removed from the fabric, by cutting or the like, after the manufacturing process.

Although examples of woven fabrics are discussed above, it will be appreciated that other textile manufacturing processes such as knitting, embroidery, crocheting, sewing, circular weaving and the like may be used to manufacture selectively conductive materials having more complicated patterns.

Referring now to the flowchart of FIG. 3, various methods may be used for manufacturing a selectively conducting fabric of the disclosure. For the sake of simplicity and so as to better explain the general principles of the disclosure, only selected actions are represented in the flowchart of FIG. 3 representing a general method for manufacturing a conductive textile. At least a first yarn is obtained of a first material having a first affinity to conductive impregnation 302, and at least a second yarn is obtained of a second material having a second affinity to conductive impregnation 304.

A fabric having at least a first region having the first affinity to conductive impregnation and at least a second region having the second affinity to conductive impregnation may be formed at least by intertwining the first yarn and the second yarn into a cloth 306. As described above, because standard yarns are used, standard fabric manufacturing techniques may be used as well known in the art.

The resulting cloth may be impregnated with conductive material 308 to produce a conductive cloth having a first region having a first conductivity and a second region having a second conductivity. It is noted that it is a particular feature of the current disclosure that because the cloth includes regions of differing affinities of conductive impregnation, the resulting cloth is selectively impregnated with conducting material in its different regions.

Various processes for introducing conductive material into cloth are known, such as electroless plating, electroplating, painting, dying, sputtering, evaporative depositing, coating with metal, coating with a conducting polymer and the like.

Electroless plating involves depositing some metallic alloy, such as nickel, copper, silver, gold, cobalt alloys or the like as well as combinations thereof, onto a substratum without the use of an electric current. Electroless plating may be used to modify the surface of fabrics such as yarn materials. In particular, many different fiber types, including acrylic, polyester, nylon, cellulosics and the like may be coated. Electroless plating may deposit conducting materials from an aqueous medium such as a solution. A metal coating may be formed as a result of a chemical reaction between a reducing agent and metal ions.

It is particularly noted that electroless plating may be used in a first phase to produce a selectively conducting substrate which may further be coated in a second phase using other techniques such as electroplating, sputtering, or the like.

Sputtering is a process usually carried out in a vacuum. An electrical potential is applied between a target cathode and the substratum which serves as an anode. A low-pressure plasma discharge is produced in which free electrons, neutral particles and positively charged atoms or argon, say, are present. Positive ions within the plasma may accelerate toward the target. Consequently the target may eject atoms into the gas phase which reach the substratum at a high velocity where they may condense forming a coating layer.

Evaporative deposition is another vacuum-based process. A metal, such as aluminium, is heated to a temperature which maximizes evaporation and fabric may be passed over a water-cooled drum where it is exposed to a metal vapor. By using a cloth having regions with different affinities to condensation, metal may condense selectively onto the fabric as required.

Additionally or alternatively, still other impregnation techniques may be used to suit requirements to render a prepared cloth of woven fabric which has regions of high affinity to conductive impregnation and regions of low affinity to conductive impregnation, thus is selectively conductive.

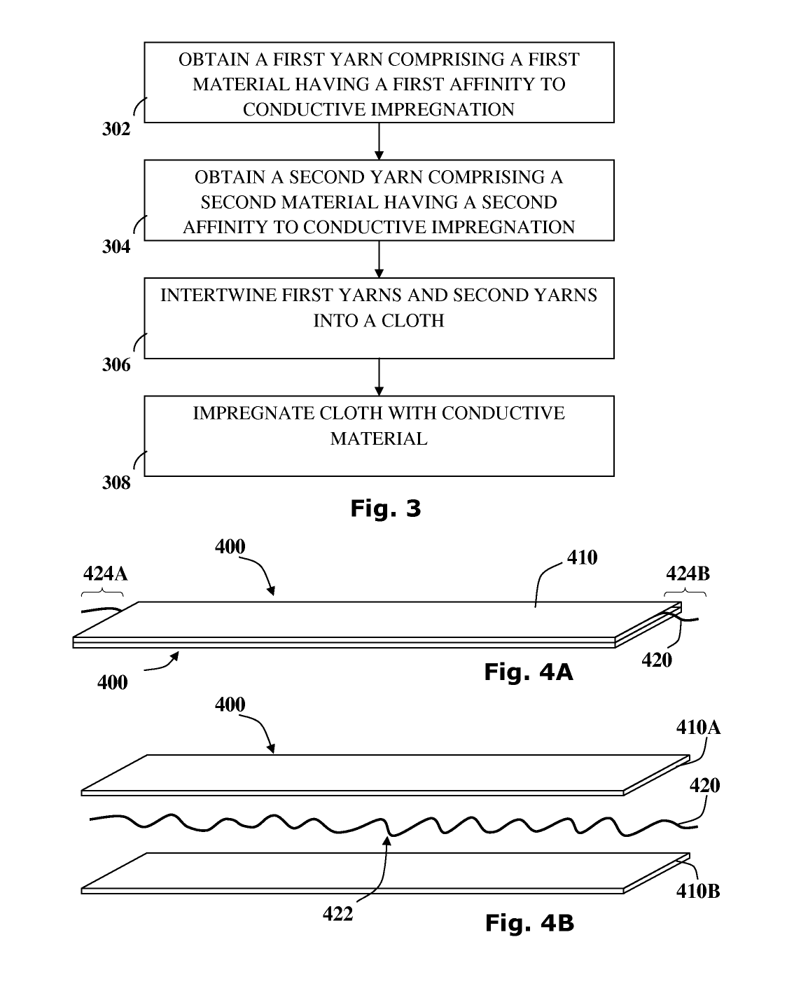

Referring now to FIGS. 4A and 4B another example of a conductive flexible material is presented. In particular FIG. 4A is an isometric view of a composite flexible conductive material 400. The composite flexible conductive material 400 includes a conductive wire 420 embedded into a flexible host material 410. Various materials may be used for the conductive wire such as stainless steel, copper, gold, silver, aluminium, carbon, or the like. Where required, semiconducting material may be used in combination or alternatively to the conducting wire.

Where required, the conducting wire 420 may extend from the ends of the host material 410. The extending sections 424A, 424B of the conducting wire 420 may provide a conducting terminus which may facilitate conductive coupling of the conductive flexible material with connecting wires and other electrical elements.

FIG. 4B shows an exploded view of the composite flexible conductive material 400 illustrating how the host material 410, may be two sheets of laminate material 410A, 410B, such as plastic films or the like, between which the conducting wire 420 is sandwiched. The laminate material may be assembled for example using heat, pressure adhesives, welding or the like.

It is a particular feature of this embodiment that the conducting wire 420 has a length significantly in excess of the length of the host material 410. Accordingly, the conducting wire 420 adopts a sinuous, or wavy, configuration consisting of multiple turns 422 to and fro along the plane of the host material.

The sinuous configuration of the conducting wire 420 may allow the flexible host material to twist, turn, stretch or otherwise reconfigure without being impeded by the mechanical properties of the conducting material of the wire. Accordingly, the elasticity, flexibility, plasticity and other mechanical properties of the composite flexible conductive material 400 may be determined by the flexible host 410 while the electrical properties may be determined by the embedded conducting wire 420.

It is noted that the electrical characteristics of the composite flexible conductive material may be further enhanced by embedding other conducting elements into the host material.

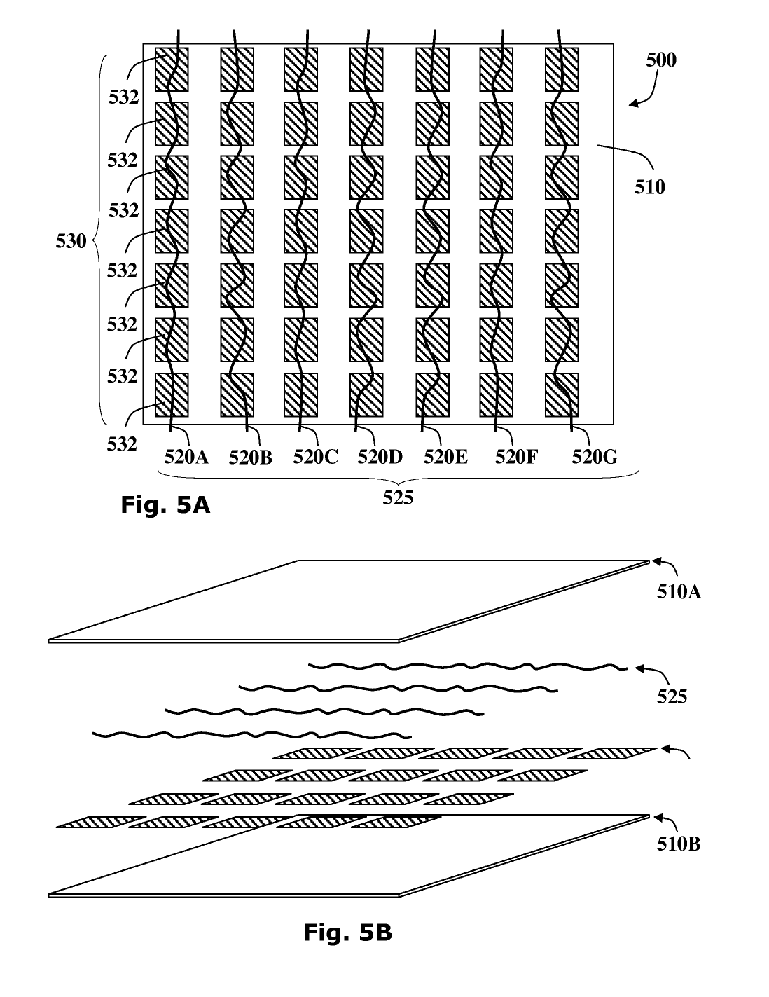

Referring now to FIGS. 5A and 5B, a schematic top view and an exploded isometric view are presented of another example of a composite flexible conductive material 500. The composite flexible conductive material 500 of the embodiment includes a flexible host material 510, an array 530 of conducting elements 532, and a network 525 of connecting wires 520A-G (collectively 520).

Such a composite flexible conductive material 500 may be used in a range of electrical applications particularly because the dimensions and configuration of the embedded elements 530 may be selected to provide a variety of characteristics as required. For example, the composite material 500 may be used to provide wide strip electrode strips or capacitance plates for use in a pressure sensor such as described herein below.

Various host materials 510 may be used to embed the electrical elements of the composite flexible conductive material 500 such as plastic films and the like. It is particularly noted, that where required, the sheets 510A, 510B of host material may be distinct, each sheet 510A, 510B being selected for its own characteristic properties. The laminate material may be assembled for example using heat, pressure adhesives, welding or the like. It is particularly noted that assembling the laminate material may have the effect of establishing good conductive connection being the conducting elements 532 and the connecting wires 520.

The array of conducting elements 530 may include a plurality of conductive element segments 532. The segmented nature of the conducting elements 532 allows the composite flexible conductive material 500 to retain its mechanical flexibility, while enhancing its electrical properties.

The network 525 of connecting wires 520 may be used to conductively couple the conducting elements 532 of the array in a variety of configurations via connecting wires 520. Accordingly, the connecting wires 520 of this embodiment may be non-insulated bare conducting wire, such as copper, gold, silver, aluminium, carbon, or the like. It is noted that the length of the connecting wire is significantly in excess of the length of the flexible host material 510. Accordingly, the connecting wires 520 adopt a sinuous, or wavy, configuration along the plane of the host material.

Where required, the network 525 of connecting wires 520 may be configured as a net, a web or the like connecting the conducting elements 532 in a desired configuration. Accordingly, the network 525 of connecting wires 520 may be knitted, crocheted, woven, sewed, knotted, tied or otherwise intertwined as described herein.

The sinuous configuration of the conducting wires 520 may allow the flexible host material 510 and embedded array of conducting elements 530 to twist, turn, stretch or otherwise reconfigure without being impeded by the mechanical properties of the individual electrical elements 532. Accordingly, the elasticity, flexibility, plasticity and other mechanical properties of the composite flexible conductive material 500 may be determined by the flexible host 510 while the electrical properties may be determined by the configuration of the embedded array of conducting elements 530 and the connecting wires 520.

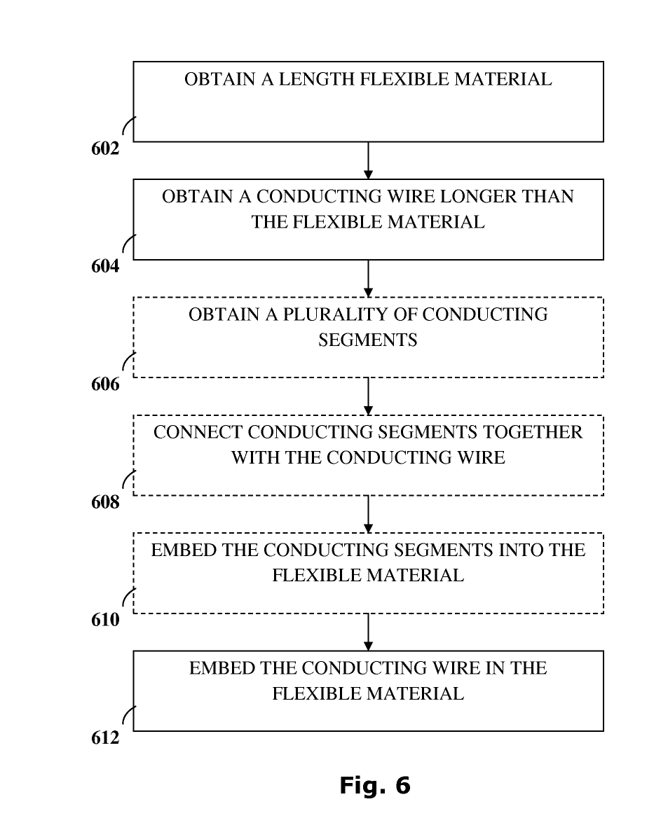

Referring now to the flowchart of FIG. 6, selected actions of a method for manufacturing a composite flexible conductive material of the disclosure are presented.

The method may include: obtaining a length of flexible material 602, obtaining a conducting wire longer than the flexible material 604, and embedding the conducting wire in the flexible material 612.

Where required, the method for manufacturing the composite flexible conductive material may further include obtaining a plurality of conducting segments or electrical elements 606, connecting the conducting segments via the conducting wire 608, and embedding the electrical elements into the flexible material 610.

For example, conducting wire may be embedded in the flexible material by laminating the conducting wire with a flexible laminate such as plastic film or the like. Lamination may be applied using a variety of methods such as thermal assembly, pressure assembly, adhesive assembly, welding, riveting, heat binding and the like, as well as combinations thereof.

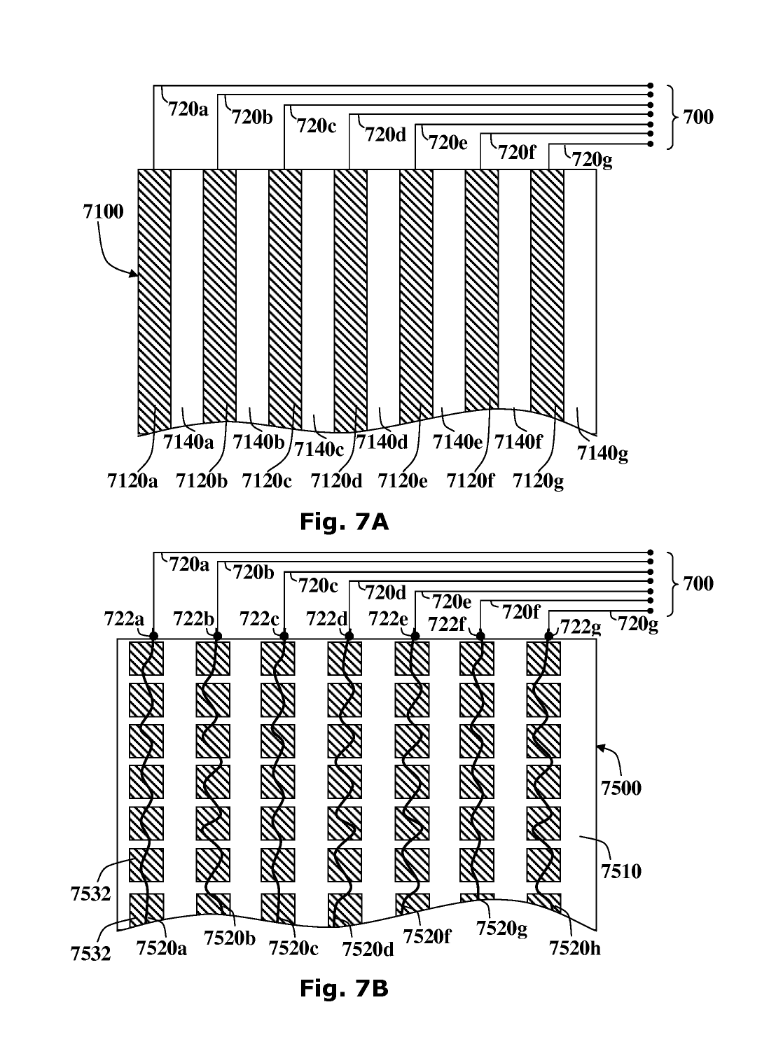

Reference is now made to FIGS. 7A and 7B which schematically represent possible embodiments of the flexible conductive materials 7100, 7500 of the disclosure configured and wired to provide flexible strip electrodes. Such strip electrodes may be used, for example, in pressure sensing mats or the like such as described hereinbelow.

Where such strip electrodes require individual control, a bundle 700 of electrical connecting lines 720 may provide a dedicated conductive path to for each electrode. Various electrical coupling configurations are described herein, although other coupling methods may occur to those skilled in the art.

With particular reference to FIG. 7A, a schematic representation is shown of a segment of selectively conducting fabric 100 wired to function as an array of strip electrodes 7120a-g for use as capacitive plates for example. The electrodes 7120a-g are regions of conducting cloth with intermediate regions 7140a-g forming inter-electrode insulators. The electrode regions 7120 may, for example, comprise material having a high affinity to conductive impregnation, such as polyester yarns, and the inter-electrode insulators 7140 may comprise a material having a low affinity to conductive impregnation, such as nylon. Following electroless plating, the polyester yarns may be impregnated with conductive material whereas the nylon yarns may not be impregnated. The resulting cloth includes an array of conductive electrode strips 7120a-g electrically insulated from each other by insulating inter-electrode regions 7140a-g.

The electrode array 7120 may be wired via a bundle 700 of electric connecting lines 720a-g, thereby providing a dedicated conductive path to each electrode 7120a-g. This dedicated path allows each electrode to be individually controlled or monitored. For example the potential, voltage, current flowing therethrough or the like may be measured and recorded for each electrode individually via a dedicated signal line. It will be appreciated that the electrical connecting lines 720a-g may be conducting wires, ribbons, flatband cables, cables or the like in conductive contact with the electrodes 7120a-g of the fabric. Alternatively or additionally, at least some of the connecting lines 720a-g may comprise conductive fabric sewn, woven or otherwise connected in conductive contact with the electrodes 7120a-g. Indeed, where applicable, the connecting lines 720a-g may also comprise yarns with high affinity to conductive impregnations which are themselves woven, knitted or otherwise incorporated into the selectively conducting fabric 7100 together with the electrodes 7120a-g during production.

Referring now to FIG. 7B which schematically represents a composite flexible conductive material 7500 in which an array of conducting segments 7532 are connected via connecting wires 7520a-h (collectively 7520) to function as an array of strip electrodes and are embedded in a host material 7510.

Each of the connecting wires 7520a-g may be connected to the electric connecting lines 720a-g via a conductive fastening 722a-g. It is particularly noted that where the connecting wires 7520 protrude from the edges of the host material 5100 the conductive fastenings 722a-g may readily connect the extending section of the connecting wires 7520a-g.

Various conductive fastenings may be used to conductively and mechanically couple the connecting wires 7520 to the connecting lines 720a-g. By way of illustration only, a selection of possible conductive fastenings are presented herein below. It will be appreciated that other fastenings may be used where required.

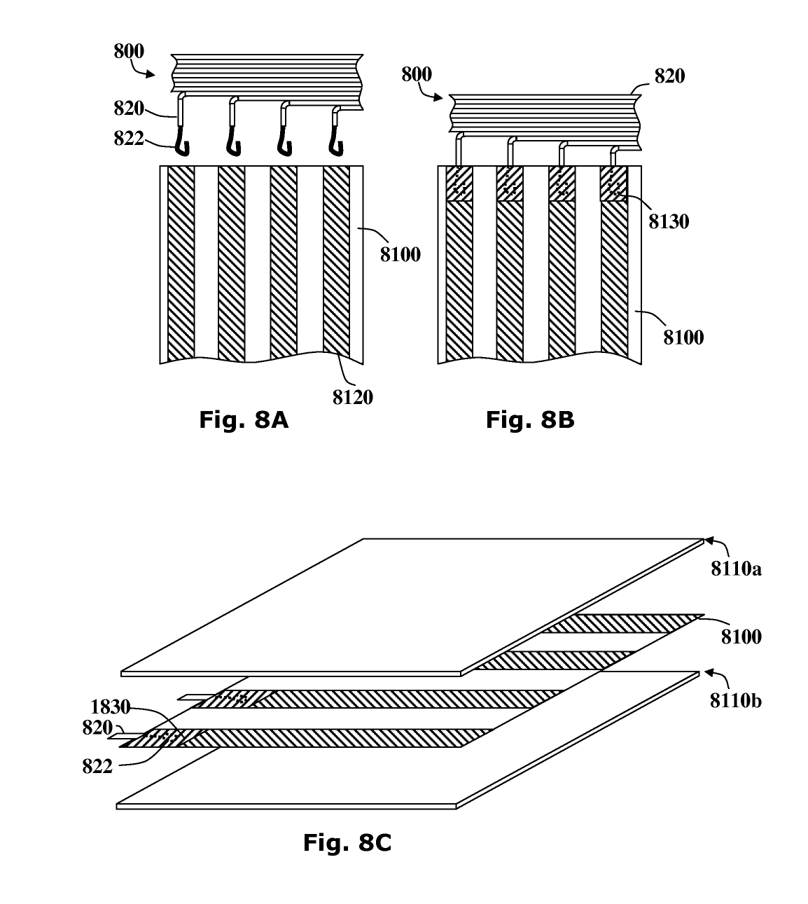

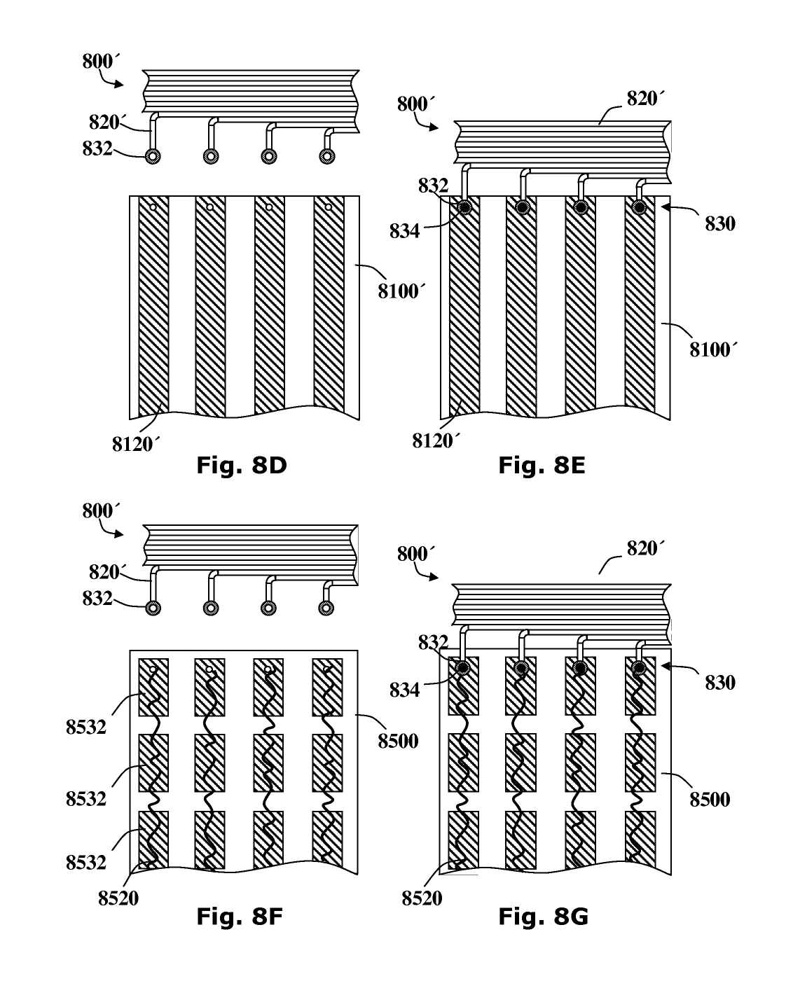

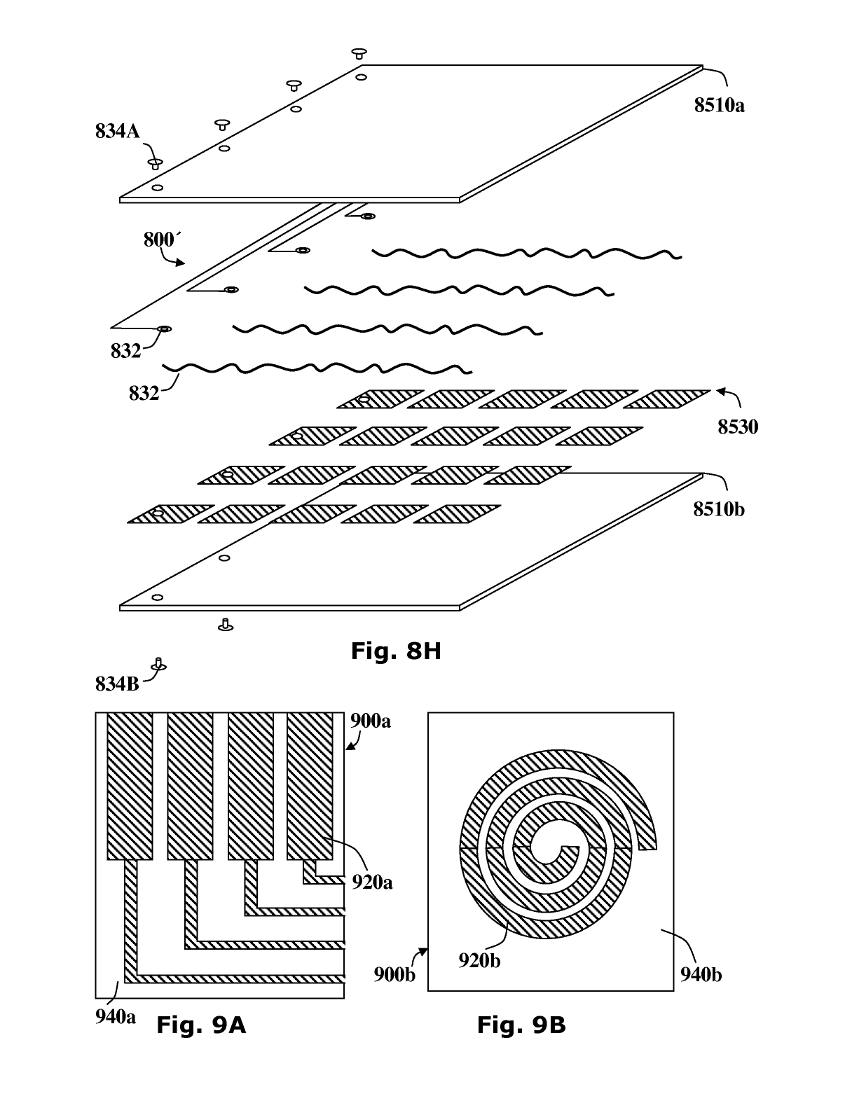

With reference now to FIGS. 8A-C, a first example is illustrated of a conductive coupling 810 for connecting a bundle of electrical connecting wires to a flexible conductive material 8100.

The flexible conductive material 8100, such as a selectively conductive fabric, a composite flexible conductive material or the like, may include an array of parallel strip electrodes 8120 which each require wiring to electrical components such as controllers, monitors or the like.

The bundle 800 of insulated electrical connecting lines 820 may be a cable such as a flatband cable or the like. Each insulated electrical connecting line 820 of the embodiment terminates in an exposed section 822 of bare, stripped or otherwise non-insulated wire.

As illustrated in FIG. 8B, the exposed section 822 of the conducting line 820 may be brought into conductive contact with an associated strip electrode 8120 of the array. Accordingly, each strip electrode 8120 may be conductively connected to a dedicated connecting line 820 from the bundle. Where required, conductive contact may be enhanced by configuring the exposed section 822 into a suitable shape such as a loop, hook, zig-zag or the like.

The exposed section 822 of the conducting line 820 may be mechanically bound to the strip electrode to prevent detachment. For example, an additional section 1830 of conducting material may be attached to the strip electrode by affixing, adhering, sewing, riveting or the like. Accordingly, the exposed section 822 of the conducting line 820 may be sandwiched between the two conducting sections resulting in a firm connection.

Referring to FIG. 8C, where appropriate, the flexible conductive material 8100 may be further treated, for example by laminating the conductive material between two laminates 8110A, 8110B, such as insulating plastic sheets, to further enhance the materials electrical and/or mechanical characteristics.

Referring now to FIGS. 8D and 8E which schematically show a riveted fastening 830 for connecting the bundle 800′ of electrical connecting lines 820′ to the flexible conductive material 8100′.

In this embodiment of the bundle 800′ of insulated electric connecting lines 820′ may be a cable, such as a flatband cable or the like, each insulated electrical connecting line 820′ terminates in a conductive ring connector 832. Accordingly, as illustrated in FIG. 8E, each conducting line 820′ of the bundle 800′ may be conductively coupled to an associated strip electrode 8120′ via a conducting rivet 834 which passes through the electrode 8120′ and the ring connector 832, thereby providing mechanical and electrical coupling of the bundle 800′ to the flexible material 8100.

Referring now to FIGS. 8F-H, the riveted fastening 830 is shown in top view and exploded isometric view connecting the bundle 800′ of electrical connecting wires 820′ to a composite flexible conductive material 8500. The composite flexible conductive material 8500, such as described herein, may include an array 8530 of embedded conducting segments 8532 conductively connected via a connecting wire 8520 and configured to function as an array of strip electrodes. Again, the bundle 800′ of insulated electric connecting lines 820′ may be a cable, such as a flatband cable or the like, each insulated electrical connecting line 820′ terminating in a conductive ring connector 832.

As indicated in the exploded view of FIG. 8H, each riveted fastening 834 of the embodiment may comprises a rivet top 834A and a rivet bottom 834B. The riveted fastening 830 may be configured to conductively couple directly with the conductive connecting wire 8520 and/or at least one of the embedded conducting segments 8530. Accordingly, the rivet top 834A may have a shaft diameter selected such that it may pass through the connecting ring 832 and a primary head diameter selected such that the connecting ring 832 is secured firmly against the conducting elements. Accordingly, each conducting line 820′ of the bundle 800′ may be conductively coupled to an associated strip electrode 8520 via a conducting rivet 834 thereby providing mechanical and electrical coupling of the bundle 800′ to the composite flexible conductive material 8500. Furthermore, the electrical elements may be embedded between flexible laminate layers 8510a, 8510b.

The above-described examples are presented for illustrative purposes only, still further conductive fastenings may be used to mechanically and/or conductively connect the components, such as clips, screws, conductive adhesives, conductive thread, clasps, hooks, locks and the like, which will occur to those skilled in the art.

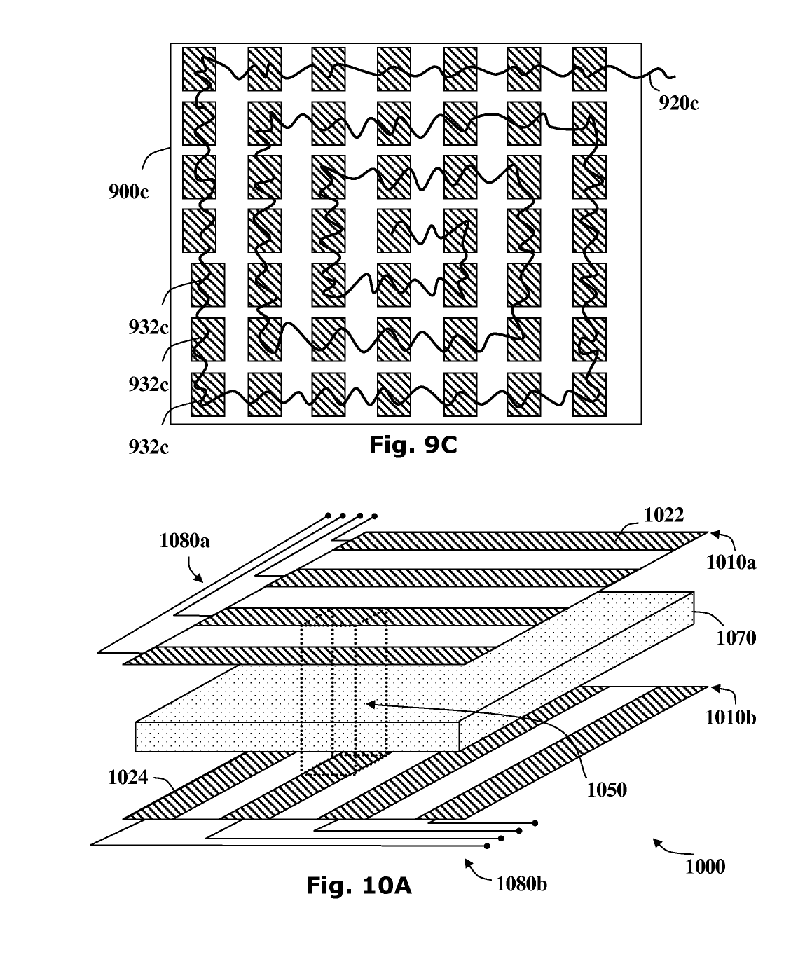

Although by way of example, embodiments of the flexible conductive material have been described which include strip electrodes. It will be appreciated that more complex conductive regions may alternatively be produced. For example, FIGS. 9A-C schematically represent further examples of flexible conductive material 900a, 900b and 900c. FIG. 9A shows a section of flexible conductive material 900a which may be produced from selectively conducting cloth of standard yarns using standard textile manufacturing techniques which are treated to produce a set of conductive regions 920a and non-conductive regions 940a which do not extend completely across the fabric. This may be used, for example, for conductively connecting an array of electrodes such as described above to a controller, or the like.

FIG. 9B schematically shows still a further example of a section of selectively conducting cloth 900b in which a conductive region 920b in the form of a coil has been fabricated in a non-conductive region 940b. Such a coil may be used, for example, as an inductor, a resistor or the like as will occur to those skilled in the art.

FIG. 9C schematically represents a composite flexible conductive material 900c in which an array of embedded conducting segments 932c are conductively connected via a connecting wire 920c and configured to form a conducting coil. It will be appreciated that other configurations of the connecting wire 920c may be selected to produce still other shapes as suit requirements.

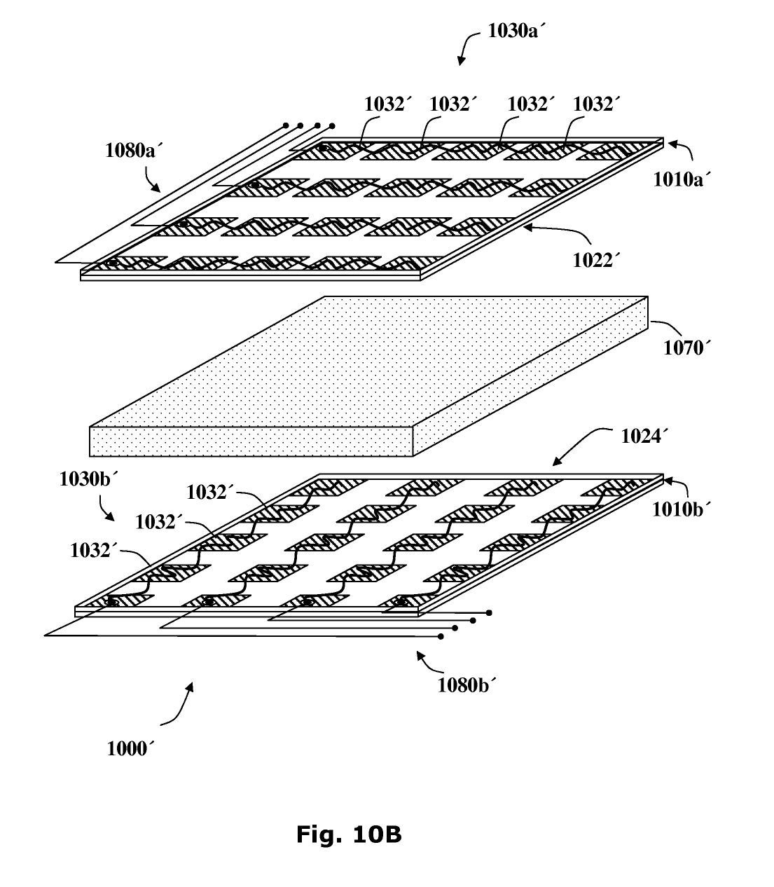

Referring now to FIGS. 10A and 10B, a particular application of the disclosure is schematically represented to illustrate one possible utility of flexible conductive materials such as described herein.

FIG. 10A is an exploded schematic isometric projection of a pressure-detection mat 1000 comprising a plurality of pressure sensors 1050 arranged in a form of a matrix. The mat 1000 includes two layers 1010a, 1010b of selectively conductive fabric separated by an insulating layer 1070 of isolating material. The two layers of selectively conductive fabric 1010a, 1010b may each include an array of strip electrodes 1022, 1024 in conductive communication with electrical connecting lines 1080a, 1080b such as described herein. The two layers of selectively conductive fabric 1010a, 1010b may be arranged orthogonally. The connecting lines 1080a, 1080b may be wired to a control unit.

Each pressure sensor 1050 may be formed at an overlapping section of the electrode strips 1022, 1024 at each intersection of a conductive strip with an orthogonal conductive strip. These pressure sensors may be configured such that pressing anywhere on their surface changes the spacing between the two conductive layers, and consequently the capacitance of the intersection. A driving unit may selectively provide an electric potential to the vertical strip 1024 and the electrical potential may be monitored on the horizontal strip 1022, or vice versa, such that the capacitance of the overlapping section may be determined.

FIG. 10B is an exploded schematic isometric projection of, an alternative embodiment of a pressure-detection mat 1000′. Here, the mat 1000′ includes two layers 1010a′, 1010b′ of composite flexible conductive material such as described herein, separated by an insulating layer 1070′ of isolating material. The two layers of composite flexible conductive material 1010a′, 1010b′ may each include an array 1030a′, 1030b′ of conductive elements 1032′ connected via sinuous connecting wires 1020′ and embedded in a flexible laminate. The arrays 1030a′, 1030b′ are configured to form two orthogonal arrays of strip electrodes 1022′, 1024′ in conductive communication, possibly via conductive riveted fasteners, with electrical connecting lines 1080a′, 1080b′ such as described herein. The connecting lines 1080a′, 1080b′ may be wired to a control unit.

It is noted that by providing an oscillating electric potential across each sensor and monitoring the alternating current produced thereby, the impedance of the intersection may be calculated and the capacitance of the intersection determined. The alternating current varies with the potential across a capacitor according to the formula:

I_{ac}=2πfCV_{ac}

where I_{ac} is the root mean squared value of the alternating current, V_{ac} is the root mean squared value of the oscillating potential across the capacitor, f is the frequency of the oscillating potential and C is the capacitance of the capacitor.

Thus where the values of V_{ac} and I_{ac} are known at a known frequency, the capacitance of a sensor may be calculated. Accordingly, where the mechanical properties of the sensor are known, the pressure applied upon the sensor may be deduced.

Preferably a capacitance sensor will retain its functionality even if it is fully pressed continuously for long periods such as or even longer than 30 days, and keep its characteristics for periods over the lifetime of the sensing mat which is typically more than a year. Notably, the sensor characteristics should preferably be consistent between two separate events.

According to some embodiments, the mat may further include additional sensors configured to monitor additional factors, particularly additional factors influencing the development of bedsores, such as temperature, humidity, moisture, or the like. Such additional sensors may be configured to monitor the factors continuously or intermittently as appropriate to detect high risk combinations of factors. Such measurements may be recorded and stored in a database for further analysis.

Optionally, additional sensors may be located apart from the pressure-detection mat. For example, the mat could be integrated into a seat of a chair and a touch sensor could be integrated into a chair's back support. Where required, additional sensors may be formed from selectively conducting material.

Selectively conductive materials, such as described herein, may be particularly advantageous to such pressure-detection mats because they are flexible. The isolating and insulating layer 1070 material may be a compressible, typically sponge-like, airy or poriferous material (e.g. foam), allowing for a significant change in density when pressure is applied to it. Materials comprising the sensing mat are typically durable enough to be resistant to normal wear-and-tear of daily use. Furthermore, the sensing mat may be configured so as not to create false pressure readings, for example when the mat is folded.

Accordingly, the pressure-detection mat 1000, 1000′ or sensing-mat, may be placed underneath or otherwise integrated with other material layers such as used in standard bed sheets. It will be appreciated that such additional materials may confer further properties as may be required for a particular application. Where required, the conductive material of the selectively conducting fabric may be further covered with an isolating, washable, water resistant, breathing cover mat, allowing minimum discomfort to the subject resting on the mat.

Accordingly the selectively conductive textile may be used to provide a pressure detection mat such as described in the applicant's co-pending international patent applications PCT/IL2012/000294, PCT/IB2011/051016, PCT/IB2011/054773 and PCT/IB2012/050829 which are incorporated herein by reference. Such a pressure detection mat may be used to prevent the development of pressure sores, decubitus ulcers and the like in subjects by providing indications prompting pressure relieving action being taken. At least one layer of an insulating material 1070, 1070′ may be sandwiched between a first electrode layer 1010a, 1010a′ of the selectively conductive textile and a second electrode layer 1010b, 1010b′ of the conductive textile, wherein the strip electrodes 1022, 1022′ of the first layer and the strip electrodes 1024, 1024′ of the second layer overlap at a plurality of intersections. A driving unit (not shown) may be configured to supply electrical potential selectively to the conducting strips 1022, 1022′ of the first layer 1010a, 1010a′ via electrical connectors 1080a, 1080a′ and a control unit (not shown) may be wired to the conductive strips 1024, 1024′ of the second layer 1010b, 1010b′ via electrical connectors 1080b, 1080b′ and operable to control the driving unit. A processor configured to monitor electrical potential on the conductive strips 1024, 1024′ of the second layer 1010b, 1010b′, to calculate impedance values for each intersection and to determine pressure applied to the intersection may be provided. Accordingly indications of pressure distribution may be displayed to at least one caregiver, for example on a visual display, such that the caregiver may take pressure relieving action upon the subject.

Technical and scientific terms used herein should have the same meaning as commonly understood by one of ordinary skill in the art to which the disclosure pertains. Nevertheless, it is expected that during the life of a patent maturing from this application many relevant systems and methods will be developed. Accordingly, the scope of the terms such as computing unit, network, display, memory, server and the like are intended to include all such new technologies a priori.

As used herein the term “about” refers to at least ±10%.

The terms “comprises”, “comprising”, “includes”, “including”, “having” and their conjugates mean “including but not limited to” and indicate that the components listed are included, but not generally to the exclusion of other components. Such terms encompass the terms “consisting of” and “consisting essentially of”.

The phrase “consisting essentially of” means that the composition or method may include additional ingredients and/or steps, but only if the additional ingredients and/or steps do not materially alter the basic and novel characteristics of the claimed composition or method.

As used herein, the singular form “a”, “an” and “the” may include plural references unless the context clearly dictates otherwise. For example, the term “a compound” or “at least one compound” may include a plurality of compounds, including mixtures thereof.

The word “exemplary” is used herein to mean “serving as an example, instance or illustration”. Any embodiment described as “exemplary” is not necessarily to be construed as preferred or advantageous over other embodiments or to exclude the incorporation of features from other embodiments.

The word “optionally” is used herein to mean “is provided in some embodiments and not provided in other embodiments”. Any particular embodiment of the disclosure may include a plurality of “optional” features unless such features conflict.

Whenever a numerical range is indicated herein, it is meant to include any cited numeral (fractional or integral) within the indicated range. The phrases “ranging/ranges between” a first indicate number and a second indicate number and “ranging/ranges from” a first indicate number “to” a second indicate number are used herein interchangeably and are meant to include the first and second indicated numbers and all the fractional and integral numerals therebetween. It should be understood, therefore, that the description in range format is merely for convenience and brevity and should not be construed as an inflexible limitation on the scope of the disclosure. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 3, 4, 5, and 6 as well as non-integral intermediate values. This applies regardless of the breadth of the range.

It is appreciated that certain features of the disclosure, which are, for clarity, described in the context of separate embodiments, may also be provided in combination in a single embodiment. Conversely, various features of the disclosure, which are, for brevity, described in the context of a single embodiment, may also be provided separately or in any suitable subcombination or as suitable in any other described embodiment of the disclosure. Certain features described in the context of various embodiments are not to be considered essential features of those embodiments, unless the embodiment is inoperative without those elements.

Although the disclosure has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present disclosure. To the extent that section headings are used, they should not be construed as necessarily limiting.

The scope of the disclosed subject matter is defined by the appended claims and includes both combinations and sub combinations of the various features described hereinabove as well as variations and modifications thereof, which would occur to persons skilled in the art upon reading the foregoing description.

1. A method for manufacturing a conductive textile comprising:
obtaining at least a first yarn comprising a first material having a first affinity to conductive impregnation;
obtaining at least a second yarn comprising a second material having a second affinity to conductive impregnation;
intertwining said first yarn and said second yarn into a cloth having at least a first region having said first affinity to conductive impregnation and at least a second region having said second affinity to conductive impregnation;
impregnating said cloth with conductive material thereby producing a conductive cloth having a first region having a first conductivity and a second region having a second conductivity.

2. The method of claim 1, wherein said step of impregnating said cloth with conductive material utilizes a process selected from at least one of the group consisting of: electroless plating, electroplating, painting, dyeing, sputtering, evaporative depositing, coating with metal, coating with a conducting polymer and combinations thereof.

3. The method of claim 1, wherein said step of intertwining said first yarn and said second yarn comprises a process selected from at least one of the group consisting of:
knitting, weaving, crocheting, tufting, embroidering and combinations thereof.

4. The method of claim 1, wherein said first material comprises nylon.

5. The method of claim 1, wherein said second material comprises polyester.

6. The method of claim 1, wherein said first material is selected from at least one of the group consisting of: nylon, cotton, wool, polyester, linen, hair, pashmina, silk, sinew, hemp, cellulose, rayon, acrylic, spandex, polythene and combinations thereof.

7. The method of claim 1, wherein said second material is selected from at least one of the group consisting of: nylon, cotton, wool, polyester, linen, hair, pashmina, silk, sinew, hemp, cellulose, rayon, acrylic, spandex, polythene and combinations thereof.

8. A conductive textile comprising at least a first yarn and at least a second yarn intertwined to form a cloth wherein said first yarn comprises a first material having a first affinity to conductive impregnation and said second yarn comprises a second material having a second affinity to conductive impregnation and said cloth is impregnated with conductive material such that said cloth has a first region having a first conductivity and a second region having a second conductivity.

9. The conductive textile of claim 8, wherein said first material comprises nylon.

10. The conductive textile of claim 8, wherein said second material comprises polyester.

11. The conductive textile of claim 8, wherein said first material is selected from at least one of the group consisting of: nylon, cotton, wool, polyester, linen, hair, pashmina, silk, sinew, hemp, cellulose, rayon, acrylic, spandex, polythene and combinations thereof.

12. The conductive textile of claim 8 wherein said first region comprises an array of conducting strip electrodes and said second region comprises an array of inter-electrode insulators.

13. A pressure detection mat comprising:
at least one layer of an insulating material sandwiched between a first layer of the conductive textile of claim 12 and second layer of the conductive textile of claim 12, wherein said strip electrodes of the first layer and said strip electrodes of the second layer overlap at a plurality of intersections;
a driving unit configured to supply electrical potential selectively to the conducting strips of the first layer;
a control unit wired to the conductive strips of the second layer and operable to control said driving unit;
a processor configured to monitor electrical potential on the conductive strips of the second layer, to calculate impedance values for each intersection and to determine pressure applied to said intersection; and
at least one display configured to present indications of pressure distribution to at least one caretaker;
such that said caretaker may take pressure relieving action upon said subject.

14-19. (canceled)
